(19) United States
(12) Patent Application Publication
(10) Pub. No.: US 2023/0371253 A1
(43) Pub. Date: Nov. 16, 2023

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventors: Jin Ho BIN, Icheon-si Gyeonggi-do (KR); Ah Reum BAHK, Icheon-si Gyeonggi-do (KR); Kyung Jin LEE, Icheon-si Gyeonggi-do (KR)

(73) Assignee: SK hynix Inc., Icheon-si Gyeonggi-do (KR)

(21) Appl. No.: 17/897,737

(22) Filed: Aug. 29, 2022

(30) Foreign Application Priority Data
May 13, 2022 (KR) 10-2022-0059089

(51) Int. Cl. H01L 27/11578; H01L 23/528; H01L 27/11551

(52) U.S. Cl. CPC H01L 27/11578; H01L 23/5283; H01L 27/11551

(57) ABSTRACT

Disclosed is a semiconductor device including a gate structure located on a source structure, and including conductive layers and insulating layers that are alternately stacked on each other, a contact plug passing through the gate structure, and electrically connected to the source structure, a stressor surrounding sidewalls of the contact plug, and a seed layer surrounding the stressor.

### CROSS-REFERENCE TO RELATED APPLICATION(S)

This application claims priority under 35 U.S.C. § 119(a) to Korean Patent Application No. 10-2022-0059089, filed on May 13, 2022, the disclosure of which is incorporated herein by reference in its entirety.

### BACKGROUND

### 1. Technical Field

Various embodiments of the present disclosure relate to an electronic device, and more particularly, to a semiconductor device and a manufacturing method of the semiconductor device.

### 2. Related Art

The degree of integration of a semiconductor device is mainly determined by an area occupied by unit memory cells. Recently, as the improvement in the degree of integration of a semiconductor device for forming memory cells as a single layer on a substrate has reached its limit, a three-dimensional semiconductor device for stacking memory cells on a substrate has been proposed. In addition, various structures and manufacturing methods are being developed to improve operational reliability of a semiconductor device having a three-dimensional structure.

### SUMMARY

In accordance with an embodiment, a semiconductor device may include: a gate structure located on a source structure, the gate structure comprising conductive layers and insulating layers that are alternately stacked on each other; a contact plug passing through the gate structure, and the contact plug electrically connected to the source structure; a stressor surrounding sidewalls of the contact plug, the stressor comprising compressive stress; and a seed layer surrounding the stressor.

In accordance with an embodiment, a semiconductor device may include: a gate structure including conductive layers and insulating layers that are alternately stacked on each other, the gate structure comprising tensile stress; a contact plug passing through the gate structure; a stressor surrounding sidewalls of the contact plug, the stressor comprising compressive stress; and a seed layer surrounding the stressor.

In accordance with an embodiment, a manufacturing method of a semiconductor device may include: forming a stack on a source structure; forming a first opening passing through the stack, and exposing the source structure; forming a seed layer in the first opening; forming a stressor comprising compressive stress by expanding the seed layer; and forming a contact plug in the stressor.

In accordance with an embodiment, a manufacturing method of a semiconductor device may include: forming a stack including first material layers and second material layers that are alternately stacked on each other; forming a first opening passing through the stack; replacing the first material layers with third material layers having tensile stress through the first opening; forming a seed layer in the opening; forming a stressor comprising compressive stress by oxidizing the seed layer; and forming a contact plug in the stressor.

### BRIEF DESCRIPTION OF THE DRAWINGS

FIGS. 1A, 1B, and 1C are diagrams illustrating a structure of a semiconductor device, in accordance with an embodiment.

FIGS. 2A, 2B, and 2C are cross-sectional views illustrating a structure of a semiconductor device, in accordance with an embodiment.

FIGS. 3A, 3B, and 3C are cross-sectional views illustrating a structure of a semiconductor device to which a stressor is applied, in accordance with an embodiment.

FIG. 4 is a flowchart illustrating a manufacturing method of a semiconductor device, in accordance with an embodiment.

FIGS. 5A, 5B, 5C, 5D, 5E, 5F, and 5G are diagrams illustrating a manufacturing method of a semiconductor device, in accordance with an embodiment.

### DETAILED DESCRIPTION

Various embodiments according to the technical spirit of the present disclosure are described below with reference to the accompanying drawings. It will be understood that when an element or layer etc., is referred to as being “on, ” “connected to” or “coupled to” another element or layer etc., it can be directly on, connected or coupled to the other element or layer etc., or intervening elements or layers etc., may be present. In contrast, when an element or layer etc., is referred to as being “directly on, ” “directly connected to” or “directly coupled to” another element or layer etc., there are no intervening elements or layers etc., present. Like numerals refer to like elements throughout.

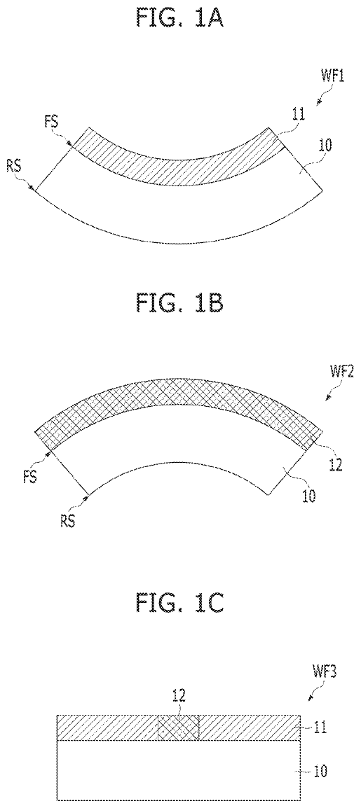

FIGS. 1A to 1C are diagrams illustrating a structure of a semiconductor device, in accordance with an embodiment.

Referring to FIG. 1A, the semiconductor device may include a first wafer structure WF1. The first wafer structure WF1 may include a substrate 10 and a first layer 11. The first layer 11 may be located on a front surface FS of the substrate 10. The first layer 11 may be contracted during a formation process thereof. The first layer 11 may have tensile stress, which may induce tensile stress of the substrate 10. The substrate 10 may be bent so that a rear surface RS thereof becomes convex, and warpage of the first wafer structure WF1 may be induced.

Referring to FIG. 1B, the semiconductor device may include a second wafer structure WF2. The second wafer structure WF2 may include a substrate 10 and a second layer 12. The second layer 12 may be located on a front surface FS of the substrate 10. The second layer 12 may expand during a formation process thereof. The second layer 12 may have compressive stress, which may induce compressive stress of the substrate 10. The substrate 10 may be bent so that a front surface FS thereof becomes convex, and warpage of the second wafer structure WF2 may be induced.

Referring to FIG. 1C, the semiconductor device may include a third wafer structure WF3. The third wafer structure WF3 may include a substrate 10, a first layer 11 and a second layer 12. The first layer 11 and the second layer 12 may be located on a front surface of the substrate 10. The first layer 11 may have tensile stress, and the second layer 12 may have compressive stress. As both of the first layer 11 and the second layer 12 are formed on the front surface of the substrate 10, the tensile stress induced by the first layer 11 may be offset by the compressive stress of the second layer 12. Accordingly, in an embodiment, warpage of the third wafer structure WF3 may be minimized or prevented.

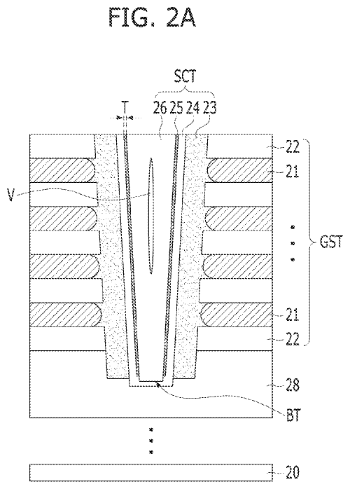

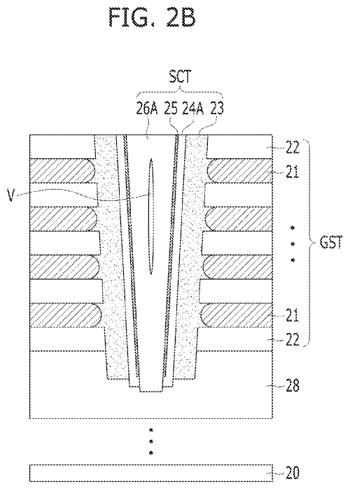

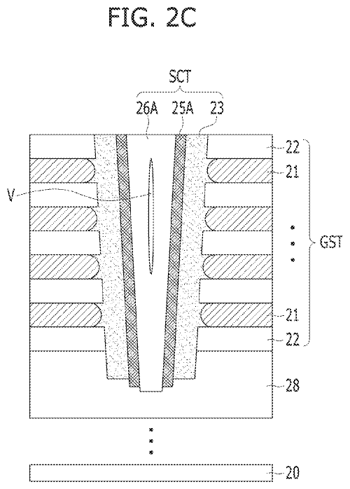

FIGS. 2A to 2C are cross-sectional views illustrating a structure of a semiconductor device, in accordance with an embodiment. Hereinafter, detailed descriptions of contents overlapping those described above are omitted.

Referring to FIG. 2A, the semiconductor device may have a wafer structure including a structure formed on a front or rear surface of a substrate 20. The semiconductor device may include a gate structure GST and a source contact structure SCT. The semiconductor device may further include the substrate 20, a source structure 28, contact plug 26, a stressor 25, a seed layer 24, an insulating spacer 23 or combinations thereof.

The source structure 28 may be located on a front surface of the substrate 20. The source structure 28 may include a conductive material such as polysilicon or metal. In an embodiment, the source structure 28 may be a conductive layer located between the substrate 20 and the gate structure GST. A substructure, such as a peripheral circuit, may be located between the source structure 28 and the substrate 20. In an embodiment, the source structure 28 may be part of the substrate 20. The source structure 28 may be an impurity region in the substrate 20.

The gate structure GST may be located on the front surface of the substrate 20, and may be located on the source structure 28. The gate structure GST may include conductive layers 21 and insulating layers 22 that are alternately stacked on each other. The conductive layers 21 may be word lines, bit lines or selection lines. The conductive layers 21 may include polysilicon, tungsten, molybdenum or a metal. The insulating layers 22 may be for insulating the stacked conductive layers from one another. The insulating layers 22 may include an insulating material such as oxide, nitride or an air gap.

The gate structure GST may have tensile stress. The conductive layers 21 may be contracted in volume during a formation process thereof, and the conductive layers 21 may have tensile stress. For reference, the structure having the tensile stress is not limited to the gate structure GST, and various structures included in the semiconductor device may each have the tensile stress.

The source contact structure SCT may pass through the gate structure GST, and be electrically connected to the source structure 28. The source contact structure SCT may include a contact plug 26 and a stressor 25. The source contact structure SCT may further include a seed layer 24, an insulating spacer 23 or a combination thereof.

The contact plug 26 may pass through the gate structure GST. The contact plug 26 may extend to the source structure 28, and be electrically connected to the source structure 28. The contact plug 26 may have a single-layered or multi-layered structure. The contact plug 26 may include a void V therein. The contact plug 26 may include a conductive material such as polysilicon, tungsten, molybdenum or metal, or combinations thereof.

The stressor 25 may be formed on the front surface of the substrate 20, and surround sidewalls of the contact plug 26. The stressor 25 may be for controlling wafer warpage. The stressor 25 may have compressive stress, and reduce or offset tensile stress of the wafer structure.

The seed layer 24 may surround the stressor 25. The seed layer 24 may remain after being used as a seed for forming the stressor 25. In an embodiment, the seed layer 24 may surround sidewalls of the stressor 25 and a bottom surface BT of the contact plug 26. The contact plug 26 may be electrically connected to the source structure 28 through the seed layer 24.

The stressor 25 may be formed by oxidizing the seed layer 24, and expand in volume during the oxidation process. The compressive stress of the stressor 25 may be induced by the expansion in volume during a formation process thereof. The seed layer 24 may include a material having a volume that expands upon oxidation. In an embodiment, the seed layer 24 may include silicon, and the stressor 25 may include silicon oxide. In an embodiment, the seed layer 24 may include polysilicon, silicon nitride, silicon oxynitride, or combinations thereof. The magnitude of the compressive stress of the stressor 25 may be determined according to a thickness T of the stressor 25. When the thickness T is large, the compressive stress may be large, and when the thickness T is small, the compressive stress may be small.

The insulating spacer 23 may surround the seed layer 24. In an embodiment, the insulating spacer 23 may surround sidewalls of the seed layer 24. The insulating spacer 23 may include protrusions protruding toward the conductive layers. The insulating spacer 23 may insulate the seed layer 24 and the conductive layers 21 from each other. The insulating spacer 23 may include an insulating material such as oxide or nitride.

Referring to FIG. 2B, the semiconductor device may include a gate structure GST, a contact plug 26A, a stressor 25, a seed layer 24A, a substrate 20, a source structure 28, an insulating spacer 23 or combinations thereof. The seed layer 24A may surround sidewalls of the stressor 25. The contact plug 26A may pass through the seed layer 24 to be directly connected to the source structure 28.

Referring to FIG. 2C, the semiconductor device may include a gate structure GST, a contact plug 26A, a stressor 25A, a substrate 20, a source structure 28, an insulating spacer 23 or combinations thereof. The semiconductor device might not include a seed layer. Alternatively, the seed layer may partially remain between the stressor 25A and the gate structure GST or between the contact plug 26A and the source structure 28.

According to the structure as described above, warpage of the semiconductor device may be adjusted using the stressor 25 or 25A. Even though a structure that induces tensile stress, such as the gate structure GST, is formed on the front surface of the substrate 20, the stressor 25 or 25A having compressive stress may be formed on the front surface of the substrate 20, thereby offsetting tensile stress of the semiconductor device. In addition, the stressor 25 or 25A may be formed in the form of a spacer surrounding the sidewalls of the contact plug 26 or 26A, thereby efficiently locating the stressor 25 or 25A in the gate structure GST. Accordingly, in an embodiment, the warpage of the semiconductor device may be minimized or prevented.

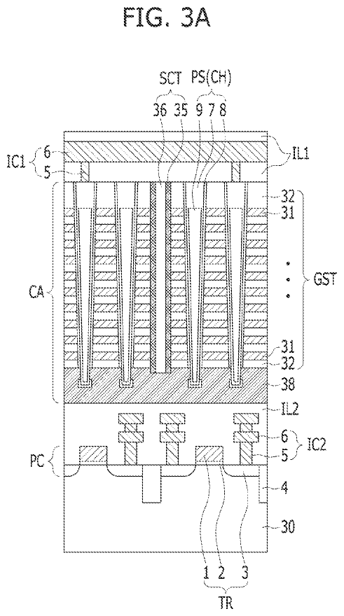

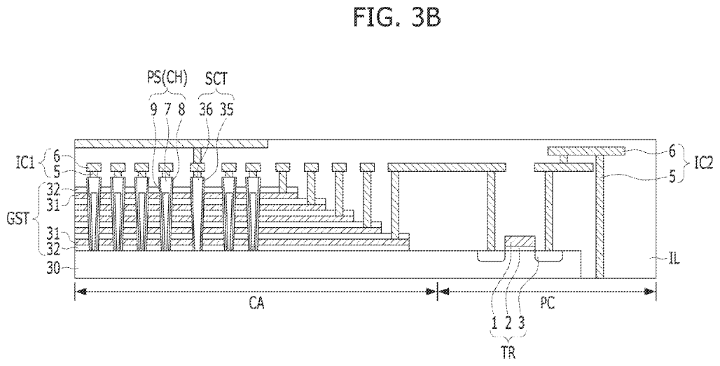

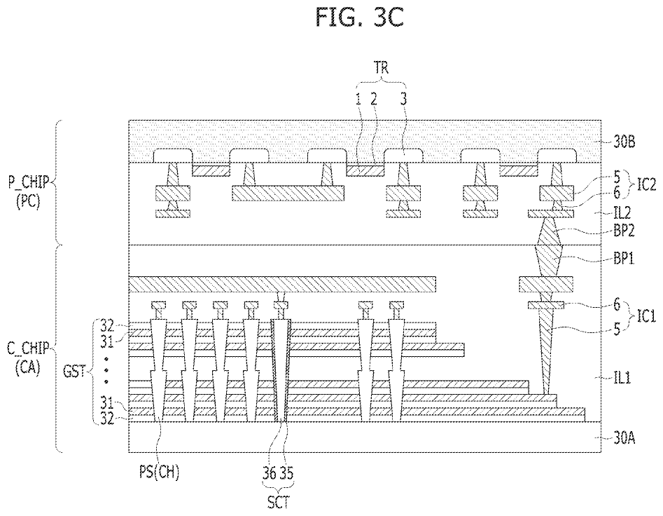

FIGS. 3A to 3C are cross-sectional views illustrating a structure of a semiconductor device to which a stressor is applied, in accordance with an embodiment. Hereinafter, detailed descriptions of contents overlapping those described above are omitted.

Referring to FIG. 3A, the semiconductor device may include a cell array CA and a peripheral circuit PC. The semiconductor device may include a substrate 30, a gate structure GST, a source contact structure SCT, a through structure PS, a first interconnection IC1, a second interconnection IC2, a first interlayer insulating layer IL1, a second interlayer insulating layer IL2 or combinations thereof. The peripheral circuit PC may be located under the cell array CA.

The cell array CA may include stacked memory cells. The cell array CA may include the gate structure GST and the source contact structure SCT, and further include a source structure 38 or the through structure PS. The gate structure GST may include conductive layers 31 and insulating layers 32 that are alternately stacked on each other. The conductive layers 31 may be word lines, bit lines or selection lines. The conductive layers 31 may include a conductive material such as polysilicon, tungsten or molybdenum.

The source contact structure SCT may include a contact plug 36 and a stressor 35 surrounding sidewalls of the contact plug 36 and having compressive stress. The source contact structure SCT may further include a seed layer or an insulating spacer. The source contact structure SCT may have a structure substantially the same as or similar to that of the embodiments described with reference to FIGS. 2A to 2C.

The through structure PS may pass through the gate structure GST, and extend to the source structure 38. Memory cells may be located at intersections of the through structure PS and the conductive layers 31.

In an embodiment, the through structure PS may be a channel structure CH. The channel structure CH may include a channel layer 7 passing through the gate structure GST, and further include a memory layer 8 surrounding outer walls of the channel layer 7 or an insulating core 9 in the channel layer 7. The memory layer 8 may include a tunneling layer, a data storage layer, a blocking layer or combinations thereof. The channel structure CH may be connected to the source structure 38 through the gate structure GST. The channel layer 7 may be directly connected to the source structure 38 or be connected to the source structure 38 through an epitaxially grown semiconductor pattern.

In an embodiment, the through structure PS may be an electrode structure. The electrode structure may include an electrode layer passing through the gate structure GST, and further include a memory layer surrounding outer or inner walls of the electrode layer. The memory layer may include a variable resistance material.

The first interlayer insulating layer IL1 may be located over the gate structure GST, and the first interconnection IC1 may be located in the first interlayer insulating layer ILL The first interconnection IC1 may include a contact plug 5 and a wiring 6. The first interconnection IC1 may be electrically connected to the through structure PS, the source contact structure SCT and the gate structure GST.

The peripheral circuit PC, which is for driving the cell array CA, may include a transistor TR, a capacitor and a resistor. The substrate 30 may include an isolation layer 4, and an active region may be defined by the isolation layer 4. The transistor TR may be located in the active region, and include a gate electrode 1, a gate insulating layer 2 and a junction 3. The gate electrode 1 may be located on the substrate 30, and the gate insulating layer 2 may be located between the gate electrode 1 and the substrate 30. The junction 3 may be located in the substrate 30 on both sides of the gate electrode 1.

The second interlayer insulating layer IL2 may be located between the substrate 30 and the source structure 38, and the second interconnection IC2 may be located in the second interlayer insulating layer IL2. The second interconnection IC2 may include the contact plug 5 and the wiring 6, and be electrically connected to the peripheral circuit PC.

Referring to FIG. 3B, the semiconductor device may include a cell array CA and a peripheral circuit PC. The semiconductor device may include a substrate 30, a gate structure GST, a source contact structure SCT, a through structure PS, a first interconnection IC1, a second interconnection IC2, an interlayer insulating layer IL or combinations thereof. The cell array CA and the peripheral circuit PC may be located adjacent to each other in a horizontal direction on the substrate 30.

Referring to FIG. 3C, the semiconductor device may include a cell chip C_CHIP and a peripheral circuit chip P_CHIP. The cell chip C_CHIP may include a cell array CA. The cell array CA may include a first substrate 30A, a gate structure GST, a source contact structure SCT, a through structure PS, a first interconnection IC1, a first interlayer insulating layer ILL a first bonding pad BP1 or combinations thereof. The peripheral circuit chip P_CHIP may include a second substrate 30B, a peripheral circuit PC, a second interconnection IC2, a second interlayer insulating film IL2, a second bonding pad BP2 or combinations thereof. By bonding the first bonding pad BP1 and the second bonding pad BP2, the peripheral circuit chip P_CHIP and the cell chip C_CHIP may be electrically connected to each other.

According to the structure as described above, the semiconductor device may include the stressor 35 having compressive stress. Accordingly, in an embodiment, tensile stress induced by various structures included in the semiconductor device may be offset through the stressor 35. Consequently, in an embodiment, warpage of the semiconductor device may be minimized or prevented.

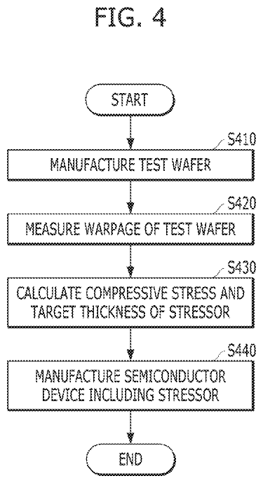

FIG. 4 is a flowchart illustrating a manufacturing method of a semiconductor device, in accordance with an embodiment.

First of all, a test wafer may be manufactured in step S410. The test wafer may be a wafer structure including a substrate and a stack formed thereon. The test wafer may have a structure similar to that of the embodiments described above with reference to FIGS. 2A to 2C or 3A to 3C, but might not include a stressor. Since the test wafer does not include a stressor, wafer warpage may be induced by tensile stress of stacked layers during the process of manufacturing the test wafer.

Subsequently, the warpage of the test wafer may be measured in step S420. A warpage measurement device may be used to measure a bending direction, a bending area and a bending degree of the test wafer. In an embodiment, as the warpage of the wafer structure is measured, the magnitude of the tensile stress induced in the process of manufacturing the test wafer may be checked.

Subsequently, a target thickness of the stressor may be calculated in step S430. In an embodiment, the stressor may be implemented to improve the warpage of the test wafer. When the wafer warpage is induced by tensile stress, the warpage, in an embodiment, may be improved by using the stressor having compressive stress. When the wafer warpage is induced by compressive stress, the warpage may be improved, in an embodiment, by using the stressor having tensile stress.

In an embodiment, as the stressor has the compressive stress, and the stressor is included in the wafer structure, the tensile stress of the wafer structure may be offset. Accordingly, in an embodiment, a position, a shape and a size of the stressor may be set to have the compressive stress capable of minimizing or offsetting the tensile stress of the wafer structure. The compressive stress of the stressor may be proportional to the thickness of the stressor. In an embodiment, the target thickness of the stressor may be set according to the magnitude of the compressive stress required to improve the wafer warpage.

The stressor may be formed by oxidizing a seed layer, and may have compressive stress as the volume thereof expands during a formation process thereof. When the amount of oxidation is large, the degree of volume expansion is large, and the compressive stress of the stressor is also large. When the amount of oxidation is small, the degree of volume expansion is small, and the compressive stress of the stressor is also small. Accordingly, in consideration of the target thickness of the stressor and the amount of increase in volume when the seed layer is oxidized, conditions for forming the stressor may be determined. A material of the seed layer, the thickness of the seed layer, the amount of oxidation of the seed layer and a recipe of the oxidation process may be set.

Subsequently, a semiconductor device may be manufactured in step S440. The semiconductor device may have a structure substantially the same as or similar to that of the test wafer, but may further include a stressor. The stressor may be formed according to a target thickness and a position of the stressor calculated based on a result of measuring the warpage of the test wafer, the material of the seed layer, the thickness of the seed layer, the amount of oxidation of the seed layer and the recipe of the oxidation process.

According to the manufacturing method as described above, the target thickness of the stressor may be calculated based on the result of measuring the warpage of the test wafer, and the semiconductor device including the stressor having the target thickness may be manufactured. Accordingly, in an embodiment, warpage of the semiconductor device may be minimized or prevented.

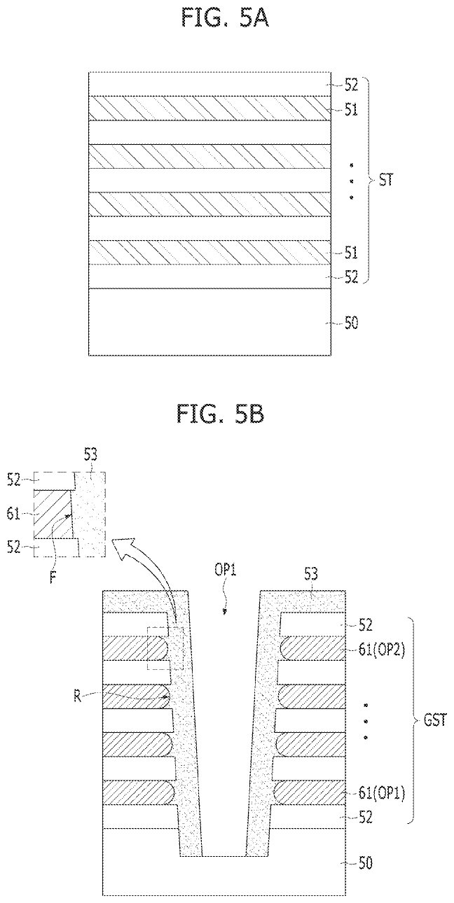

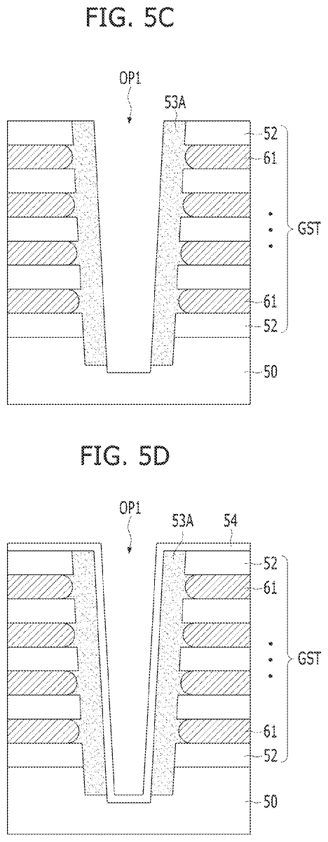

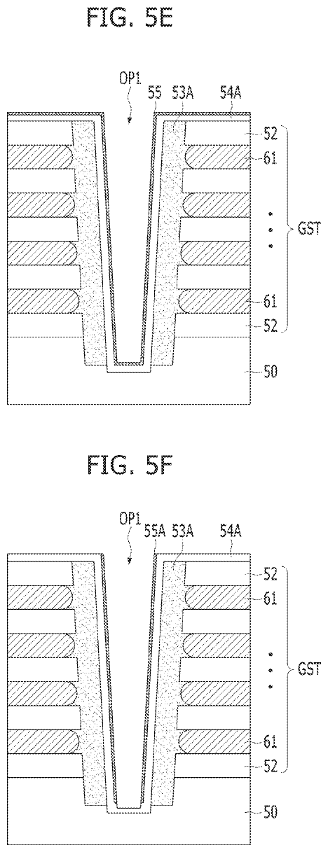

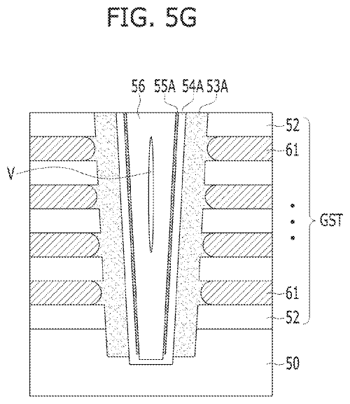

FIGS. 5A to 5G are diagrams illustrating a manufacturing method of a semiconductor device, in accordance with an embodiment.

Referring to FIG. 5A, a source structure 50 may be formed. In an embodiment, the source structure 50 may include a conductive layer located on a substrate, and include polysilicon, tungsten and a metal. The source structure 50 may be an impurity region included in the substrate.

Subsequently, a stack ST may be formed on the source structure 50. The stack ST may include first material layers 51 and second material layers 52 that are alternately stacked on each other. The first material layers 51 may be used to form a word line, a bit line and a selection line, and the second material layers 52 may be used to form an insulating layer. The first material layers 51 may include a material having a high etch selectivity with respect to the second material layers 52. For example, the first material layers 51 may include a sacrificial material such as nitride, and the second material layers 52 may include an insulating material such as oxide. For another example, the first material layers 51 may include a conductive material such as polysilicon, tungsten or molybdenum, and the second material layers 52 may include an insulating material such as oxide.

Referring to FIG. 5B, a first opening OP1 passing through the stack ST may be formed. The first opening OP1 may expose the source structure 50. For reference, although not illustrated in the drawing, a through structure passing through the stack ST may be formed before the first opening OP1 is formed.

Subsequently, the first material layers 51 may be replaced with third material layers 61 through the first opening OP1. In an embodiment, the first material layers 51 are removed through the first opening OP1 to form second openings OP2. Subsequently, third material layers 61 are respectively formed in the second openings OP2. After a third material is deposited to fill the second openings OP2, some formed in the first opening OP1 among the third material layers 61 may be etched to form the third material layers 61 separated from one another. Each of the third material layers 61 may have a round sidewall R or a flat sidewall F depending on an etching method.

The third material layers 61 may include a conductive material such as a metal. The replacing of the first material layers 51 with third material layers 61 may induce the tensile stress by contraction of the third material layers 61. The third material layers 61 may be contracted during a formation process thereof, and have tensile stress. For reference, when the first material layers 51 include a conductive material, it is also possible to perform a silicidation process instead of replacing the first material layers 51 with the third material layers 61.

Accordingly, a gate structure GST including conductive layers and insulating layers that are alternately stacked on each other may be formed. The gate structure GST may have a structure having a large aspect ratio, and have tensile stress.

Subsequently, a spacer layer 53 may be formed in the first opening OP1. The spacer layer 53 may be conformally formed along profiles of the first opening OP1 and the gate structure GST. The spacer layer 53 may be formed along an inner surface of the first opening OP1, and be formed along a top surface of the gate structure GST. The spacer layer 53 may include an insulating material such as oxide or nitride.

Referring to FIG. 5C, a spacer 53A may be formed. In an embodiment, the spacer layer 53 may be etched over a front surface thereof, and remove a portion of the spacer layer 53, which is formed on the top surface of the gate structure GST and a portion of the spacer layer 53, which is formed on a bottom surface of the first opening OP1. Accordingly, the source structure 50 may be exposed on the bottom surface of the first opening OP1, and the spacer 53A may be formed on an inner wall of the first opening OP1.

Referring to FIG. 5D, a seed layer 54 may be formed in the first opening OP1. The seed layer 54 may be conformally formed along the profiles of the first opening OP1 and the gate structure GST. The seed layer 54 may be formed along the inner surface of the first opening OP1, and be formed along the top surface of the gate structure GST. The material, thickness, etc. of the seed layer 54 may be determined according to the result of measuring the warpage of the test wafer. In an embodiment, the seed layer 54 may include a material that has a volume of which expands upon oxidation. The seed layer 54 may include silicon.

Referring to FIG. 5E, a stressor layer 55 having compressive stress may be formed. The stressor layer 55 may be formed by expanding the seed layer 54. In an embodiment, the stressor layer 55 may be formed by oxidizing the seed layer 54. A surface of the seed layer 54 may be oxidized by the oxidation process. As the silicon included in the seed layer 54 is oxidized, the volume of the seed layer may expand, and compressive stress may be induced due to the volume expansion. The target thickness of the stressor layer 55, the recipe for the oxidation process, etc. may be determined according to the result of measuring the warpage of the test wafer.

When the stressor layer 55 is formed, the seed layer 54 may be oxidized to a partial thickness or to be oxidized to a full thickness. The oxidized thickness of the seed layer 54 may vary depending on a region. Accordingly, the thickness of a remaining seed layer 54A may be uniform or vary. Alternatively, the seed layer 54A may partially remain.

Referring to FIG. 5F, a stressor 55A may be formed. In an embodiment, the stressor layer 55 may be etched over a front surface thereof, and form the stressor 55A. Accordingly, a portion of the stressor layer 55, which is formed on the bottom surface of the first opening OP1 or a portion of the stressor layer 55, which is formed on the top surface of the gate structure GST, may be removed, and the stressor 55A may be formed on the inner wall of the first opening OP1.

When the stressor layer 55 is etched, the seed layer 54A may be etched. A portion of the seed layer 54A, which is formed on the bottom surface of the first opening OP1 or a portion of the seed layer 54A, which is formed on the top surface of the gate structure GST, may be removed. As the seed layer 54A is etched, the source structure 50 may be exposed through the bottom surface of the first opening OP1. Alternatively, the seed layer 54A may remain on the bottom surface of the first opening OP1.

Referring to FIG. 5G, a contact plug 56 may be formed in the first opening OP1. The contact plug 56 may include a void V therein. In an embodiment, after a conductive layer is formed to fill the first opening OP1, the conductive layer may be planarized until the top surface of the gate structure GST is exposed, and thus the contact plug 56 may be formed. In the process of planarizing the conductive layer, the seed layer 54A remaining on the top surface of the gate structure GST may be removed together.

According to the manufacturing method as described above, the stressor 55A having compressive stress may be formed on sidewalls of the contact plug 56. As the stressor 55A is formed to have the target thickness calculated from the warpage of the test wafer, it is possible, in an embodiment, to minimize or prevent the warpage of the semiconductor device. In addition, after measuring the warpage of the semiconductor device including the stressor 55A, the target thickness of the stressor 55A, in an embodiment, may be corrected according to the measurement result. Accordingly, in an embodiment, it is possible to correct the warpage of the semiconductor device to be manufactured later.

An embodiment of the present disclosure is directed to a semiconductor device having a stable structure and improved characteristics, and a manufacturing method thereof.

According to an embodiment of the present disclosure, it is possible to provide a semiconductor device having a stable structure and improved reliability.

While the present disclosure has been illustrated and described with respect to specific embodiments, the disclosed embodiments are provided for the description, and not intended to be restrictive. Further, it is noted that the present disclosure may be achieved in various ways through substitution, change, and modification that fall within the scope of the following claims, as those skilled in the art will recognize in light of the present disclosure.

What is claimed is:

1. A semiconductor device comprising:
a gate structure located on a source structure, the gate structure comprising conductive layers and insulating layers that are alternately stacked on each other;
a contact plug passing through the gate structure, the contact plug electrically connected to the source structure;
a stressor surrounding a sidewall of the contact plug, the stressor comprising compressive stress; and
a seed layer surrounding the stressor.

2. The semiconductor device of claim 1, wherein the seed layer includes a material, the material comprising a volume that expands upon oxidation.

3. The semiconductor device of claim 1,
wherein the seed layer includes silicon, and
wherein the stressor includes silicon oxide.

4. The semiconductor device of claim 1, wherein the seed layer includes polysilicon, silicon nitride, silicon oxynitride or combinations thereof.

5. The semiconductor device of claim 1, wherein the seed layer surrounds a sidewall of the stressor.

6. The semiconductor device of claim 1, wherein the seed layer surrounds a sidewall of the stressor and a bottom surface of the contact plug.

7. The semiconductor device of claim 1, further comprising an insulating spacer surrounding the seed layer.

8. The semiconductor device of claim 1, wherein the contact plug is directly connected to the source structure.

9. The semiconductor device of claim 1, wherein the contact plug is electrically connected to the source structure through the seed layer.

10. The semiconductor device of claim 1, wherein tensile stress of the semiconductor device is offset by the compressive stress of the stressor.

11. A semiconductor device comprising:
a gate structure including conductive layers and insulating layers that are alternately stacked on each other, the gate structure comprising tensile stress;
a contact plug passing through the gate structure;
a stressor surrounding a sidewall of the contact plug, the stressor comprising compressive stress; and
a seed layer surrounding the stressor.

12. The semiconductor device of claim 11, wherein the seed layer includes a material, the material comprising a volume that expands upon oxidation.

13. The semiconductor device of claim 11,
wherein the seed layer includes silicon, and
wherein the stressor includes silicon oxide.

14. A manufacturing method of a semiconductor device, comprising:
forming a stack on a source structure;
forming a first opening passing through the stack, and exposing the source structure;
forming a seed layer in the first opening;
forming a stressor comprising compressive stress by expanding the seed layer; and
forming a contact plug in the stressor.

15. The manufacturing method of claim 14, wherein the forming of the stressor includes oxidizing the seed layer to form the stressor.

16. The manufacturing method of claim 14, wherein the forming of the stack includes:
forming first material layers and second material layers that are alternately stacked on each other; and
replacing the first material layers with third material layers having tensile stress.

17. The manufacturing method of claim 14, further comprising forming an insulating spacer in the first opening before the stressor is formed.

18. The manufacturing method of claim 14, wherein the seed layer includes a material, the material comprising a volume that expands upon oxidation.

19. The manufacturing method of claim 14,
wherein the seed layer includes silicon, and
wherein the stressor includes silicon oxide.

20. The manufacturing method of claim 14, further comprising:
forming a test wafer;
measuring warpage of the test wafer; and
calculating a target thickness of the stressor for offsetting the warpage of the test wafer.

21. The manufacturing method of claim 14, further comprising:
measuring warpage of the semiconductor device including the stressor; and
correcting a target thickness of the stressor according to a result of measuring the warpage of the semiconductor device.

22. A manufacturing method of a semiconductor device, comprising:
forming a stack including first material layers and second material layers that are alternately stacked on each other;
forming a first opening passing through the stack;
replacing the first material layers with third material layers having tensile stress through the first opening;
forming a seed layer in the first opening;
forming a stressor comprising compressive stress by oxidizing the seed layer; and
forming a contact plug in the stressor.

23. The manufacturing method of claim 22, wherein the replacing of the first material layers with third material layers induces the tensile stress by contraction of the third material layers.

24. The manufacturing method of claim 22, further comprising forming an insulating spacer in the first opening before the stressor is formed.

25. The manufacturing method of claim 22, wherein the seed layer includes a material, the material comprising a volume that expands upon oxidation.

26. The manufacturing method of claim 22,
wherein the seed layer includes silicon, and
wherein the stressor includes silicon oxide.
